(19) United States
(12) Patent Application Publication
(10) Pub. No.: US 2025/0098243 A1
(43) Pub. Date: Mar. 20, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Yuta SATO, Himeji Hyogo (JP); Toru SHONO, Himeji Hyogo (JP); Koji ONISHI, Ibo Hyogo (JP)

(21) Appl. No.: 18/600,434

(22) Filed: Mar. 8, 2024

(30) Foreign Application Priority Data
Sep. 14, 2023 (JP) 2023-149462

(51) Int. Cl. H01L 29/06; H01L 29/423

(52) U.S. Cl. CPC H10D 62/124; H10D 64/514

(57) ABSTRACT

According to one embodiment, a semiconductor device includes first and second electrodes, first to third semiconductor regions, a pair of gate electrodes. The pair of gate electrodes are located on the first semiconductor region with gate insulating layers respectively interposed. A distance between the gate insulating layers in a second direction perpendicular to a first direction from the first electrode toward the first semiconductor region is not less than 150 nm and not more than 450 nm. The second semiconductor region is located between the pair of gate electrodes. The second electrode includes a contact part contacting the third semiconductor region and a portion of the second semiconductor region in the second direction. A length in the second direction of a bottom portion of the contact part is greater than 28 nm and not more than 206 nm.

### CROSS-REFERENCE TO RELATED APPLICATIONS

This application is based upon and claims the benefit of priority from Japanese Patent Application No. 2023-149462, filed on Sep. 14, 2023; the entire contents of which are incorporated herein by reference.

### FIELD

Embodiments of the invention generally relate to a semiconductor device.

### BACKGROUND

Semiconductor devices such as metal-oxide-semiconductor field-effect transistors (MOSFETs) and the like are used in applications such as power conversion and the like. It is desirable for the on-resistance of such a semiconductor device to be low.

### BRIEF DESCRIPTION OF THE DRAWINGS

FIG. 1 is a perspective cross-sectional view showing a portion of a semiconductor device according to an embodiment;

FIG. 2 is an enlarged cross-sectional view of a portion of FIG. 1;

FIG. 3 is an enlarged cross-sectional view of the portion of FIG. 1;

FIG. 4 is a simulation result of semiconductor device characteristics;

FIG. 5 is a simulation result of semiconductor device characteristics;

FIG. 6 is a simulation result of semiconductor device characteristics;

FIG. 7 is a simulation result of semiconductor device characteristics;

FIG. 8 is a simulation result of semiconductor device characteristics;

FIGS. 9A and 9B are cross-sectional views showing a method for manufacturing the semiconductor device according to the embodiment;

FIGS. 10A and 10B are cross-sectional views showing the method for manufacturing the semiconductor device according to the embodiment;

FIGS. 11A and 11B are cross-sectional views showing the method for manufacturing the semiconductor device according to the embodiment;

FIGS. 12A and 12B are cross-sectional views showing the method for manufacturing the semiconductor device according to the embodiment; and

FIG. 13 is a cross-sectional view showing the method for manufacturing the semiconductor device according to the embodiment.

### DETAILED DESCRIPTION

According to one embodiment, a semiconductor device includes a first electrode, a first semiconductor region of a first conductivity type, a pair of gate electrodes, a second semiconductor region of a second conductivity type, a third semiconductor region of the first conductivity type, and a second electrode. The first semiconductor region is located on the first electrode. The pair of gate electrodes are located on the first semiconductor region with gate insulating layers respectively interposed. A distance between the gate insulating layers in a second direction perpendicular to a first direction is not less than 150 nm and not more than 450 nm. The first direction is from the first electrode toward the first semiconductor region. The second semiconductor region is located between the pair of gate electrodes. The third semiconductor region is located on the second semiconductor region. The second electrode is located on the pair of gate electrodes with insulating layers respectively interposed. The second electrode includes a contact part contacting the third semiconductor region and a portion of the second semiconductor region in the second direction. A length in the second direction of a bottom portion of the contact part is greater than 28 nm and not more than 206 nm.

Various embodiments will be described hereinafter with reference to the accompanying drawings. The drawings are schematic and conceptual; and the relationships between the thickness and width of portions, the proportions of sizes among portions, etc., are not necessarily the same as the actual values thereof. Further, the dimensions and proportions may be illustrated differently among drawings, even for identical portions. In the specification and drawings, components similar to those described or illustrated in a drawing thereinabove are marked with like reference numerals, and a detailed description is omitted as appropriate.

In the following description, the notations of n⁺, n⁻, p⁺, and p indicate relative levels of the impurity concentrations of the conductivity types. In other words, n⁺ indicates that the n-type impurity concentration is relatively higher than that of n⁻. p⁺ indicates that the p-type impurity concentration is relatively higher than that of p. According to the embodiments described below, each embodiment may be implemented by inverting the p-type and the n-type of the semiconductor regions.

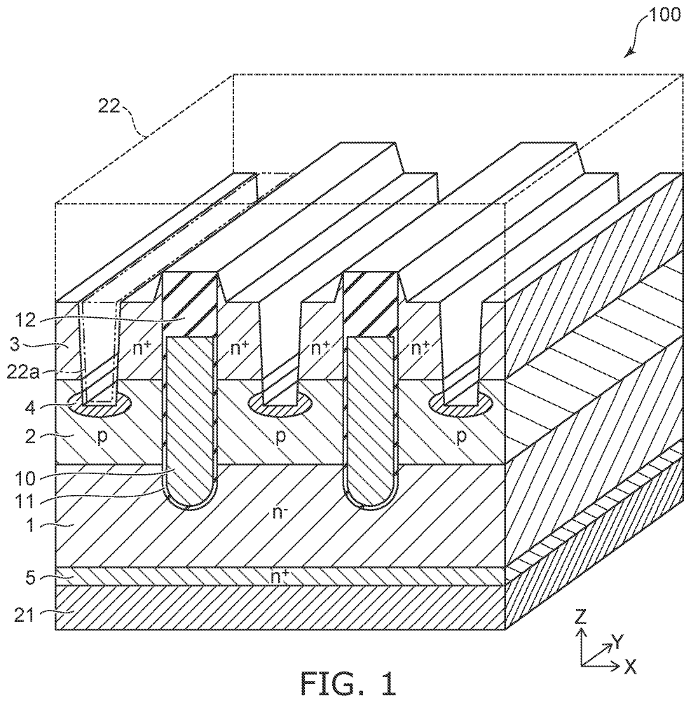

FIG. 1 is a perspective cross-sectional view showing a portion of a semiconductor device according to an embodiment.

The semiconductor device 100 according to the embodiment is a MOSFET. As shown in FIG. 1, the semiconductor device 100 includes an n⁻-type (first-conductivity-type) drift region 1 (a first semiconductor region), a p-type (second-conductivity-type) base region 2 (a second semiconductor region), an n⁺-type source region 3 (a third semiconductor region), a p⁺-type contact region 4 (a fourth semiconductor region), an n⁺-type drain region 5, a gate electrode 10, a gate insulating layer 11, an insulating layer 12, a drain electrode 21 (a first electrode), and a source electrode 22 (a second electrode). In FIG. 1, the source electrode 22 is illustrated by a broken line.

An XYZ orthogonal coordinate system is used in the description of embodiments. The direction from the drain electrode 21 toward the n⁻-type drift region 1 is taken as a Z-direction (a first direction). Two mutually-orthogonal directions perpendicular to the Z-direction are taken as an X-direction (a second direction) and a Y-direction (a third direction). In the description, the direction from the drain electrode 21 toward the n⁻-type drift region 1 is called “up/upward/above/higher than”, and the opposite direction is called “down/downward/below/lower than”. These directions are based on the relative positional relationship between the drain electrode 21 and the n⁻-type drift region 1, and are independent of the direction of gravity.

The drain electrode 21 is located at the lower surface of the semiconductor device 100. The n⁺-type drain region 5 is located on the drain electrode 21 and electrically connected with the drain electrode 21. The n⁻-type drift region 1 is located on the n⁺-type drain region 5. The n⁻-type drift region 1 is electrically connected with the drain electrode 21 via the n⁺-type drain region 5. The n-type impurity concentration of the n⁻-type drift region 1 is less than the n-type impurity concentration of the n⁺-type drain region 5.

The gate electrode 10 is located on the n⁻-type drift region 1 with the gate insulating layer 11 interposed. Multiple gate electrodes 10 are arranged in the X-direction; and these gate electrodes 10 are separated from each other. The p-type base region 2 is located between adjacent gate electrodes 10. The p-type base region 2 is positioned on the n⁻-type drift region 1. The n⁺-type source region 3 is located on the p-type base region 2. The gate electrode 10 faces a portion of the n⁻-type drift region 1, the p-type base region 2, and a portion of the n⁺-type source region 3 in the X-direction via the gate insulating layer 11.

The source electrode 22 is located on the multiple gate electrodes 10 with the insulating layers 12 respectively interposed. The source electrode 22 is positioned at the upper surface of the semiconductor device 100 and is electrically connected with the p-type base region 2 and the n⁺-type source region 3. The source electrode 22 includes a contact part 22a. The contact part 22a extends downward and contacts the n⁺-type source region 3 and a portion of the p-type base region 2 in the X-direction. The p⁺-type contact region 4 is located between the p-type base region 2 and the contact part 22a. The p-type impurity concentration of the p⁺-type contact region 4 is greater than the p-type impurity concentration of the p-type base region 2.

The p-type base region 2, the n⁺-type source region 3, the p⁺-type contact region 4, the gate electrode 10, and the contact part 22a each extend in the Y-direction and have stripe shapes.

Operations of the semiconductor device 100 will now be described. A voltage that is not less than a threshold is applied to the gate electrode 10 in a state in which a positive voltage with respect to the source electrode 22 is applied to the drain electrode 21. As a result, a channel (an inversion layer) is formed in the p-type base region 2. Electrons flow from the source electrode 22 toward the n⁻-type drift region 1 via the channel; and the semiconductor device 100 is set to an on-state. Subsequently, when the voltage applied to the gate electrode 10 drops below the threshold, the channel in the p-type base region 2 disappears, and the semiconductor device 100 is set to an off-state.

Examples of the materials of the components will now be described. The n⁻-type drift region 1, the p-type base region 2, the n⁺-type source region 3, the p⁺-type contact region 4, and the n⁺-type drain region 5 include silicon, silicon carbide, gallium nitride, or gallium arsenide as a semiconductor material. When silicon is used as the semiconductor material, arsenic, 30 phosphorus, or antimony can be used as the n-type impurity. Boron can be used as the p-type impurity. The gate electrode 10 includes a conductive material such as polysilicon, etc. The gate insulating layer 11 and the insulating layer 12 include insulating materials such as silicon oxide, etc. The drain electrode 21 and the source electrode 22 include metals such as titanium, gold, aluminum, etc. The specific materials and compositions of the drain electrode 21 and the source electrode 22 are modifiable as appropriate as long as the drain electrode 21 and the source electrode 22 can have ohmic contacts with the semiconductor regions.

Favorable ranges of the impurity concentrations of the semiconductor regions are as follows. The n-type impurity concentration in the n⁻-type drift region 1 is not less than 1.0×10¹⁶ atoms/cm³ and not more than 1.0×10¹⁸ atoms/cm³. The p-type impurity concentration in the p-type base region 2 is not less than 1.0×10¹⁷ atoms/cm³ and not more than 1.0×10¹⁹ atoms/cm³. The n-type impurity concentration in the n⁺-type source region 3 is not less than 5.0×10¹⁸ atoms/cm³ and not more than 5.0×10²⁰ atoms/cm³. The p-type impurity concentration in the p⁺-type contact region 4 is not less than 5.0×10¹⁸ atoms/cm³ and not more than 5.0×10²⁰ atoms/cm³. The n-type impurity concentration in the n⁺-type drain region 5 is not less than 1.0×10¹⁹ atoms/cm³ and not more than 1.0×10²¹ atoms/cm³.

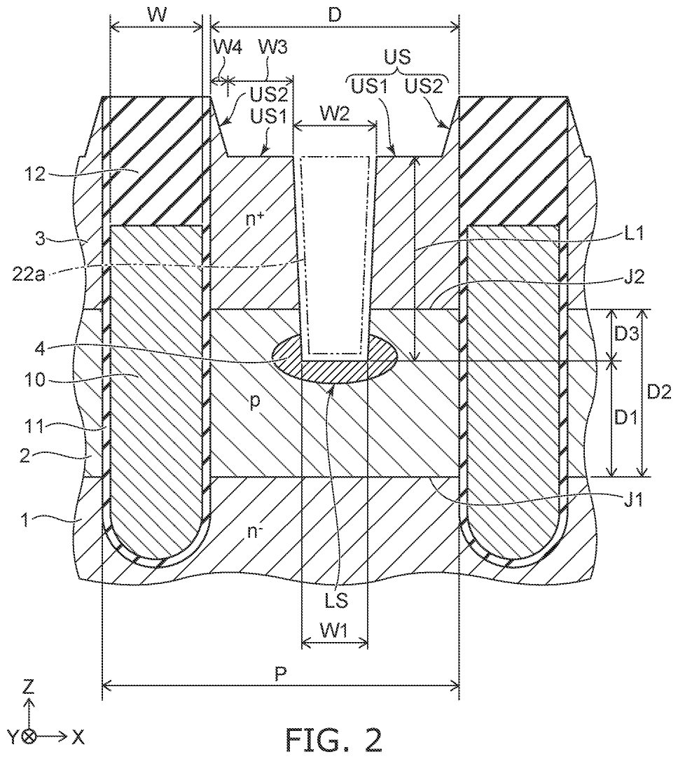

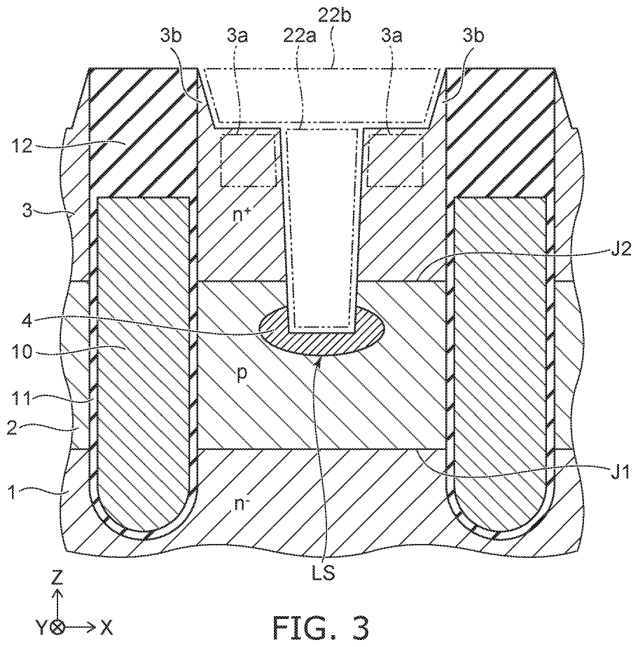

FIGS. 2 and 3 are enlarged cross-sectional views of a portion of FIG. 1.

FIGS. 2 and 3 are enlarged cross-sectional views of the same portion of the semiconductor device 100. Detailed structures and specific dimensions of the components of the semiconductor device 100 are described with reference to FIGS. 2 and 3.

The p-type base region 2 and the gate electrode 10 are alternately arranged in the X-direction. It is favorable for a distance D between the pair of gate insulating layers 11 adjacent in the X-direction to be not less than 150 nm and not more than 450 nm. It is favorable for a width W of the gate electrode 10 to be not less than 160 nm and not more than 240 nm. For example, the thickness of the gate insulating layer 11 is 20 nm. It is favorable for the thickness of the gate insulating layer 11 to be not less than 10 nm and not more than 30 nm. The sum of the distance D, the width W, and 2 times the thickness of the gate insulating layer 11 also is called the pitch of the gate electrodes 10. It is favorable for the pitch of the gate electrodes 10 to be not less than 450 nm and not more than 650 nm.

A width W1 of the contact part 22a is greater than 28 nm and not more than 206 nm. “Width” is the X-direction length. It is favorable for a length L1 in the Z-direction of the contact part 22a to be not less than 250 nm and not more than 450 nm. The side surface of the contact part 22a may be inclined with respect to the Z-direction. It is favorable for the incline with respect to the Z-direction of the side surface of the contact part 22a to be not less than 0 degrees and not more than 5 degrees.

When the side surface of the contact part 22a is inclined, the width W1 corresponds to the width of the lower end of the contact part 22a. In such a case, it is favorable for a width W2 of the upper end of the contact part 22a to be greater than 50 nm and not more than 270 nm. More specifically, the contact part 22a of the source electrode 22 refers to a part positioned between the gate insulating layers 11 and between the insulating layers 12 in the X-direction and has a width that is substantially constant in the Y-direction. The upper end of the contact part 22a refers to the end portion of the upper side of the part having the constant width. When the side surface of the contact part 22a is not inclined, the width W2 is equal to the width W1.

When the side surface of the contact part 22a is inclined, the width W and the distance D refer to X-direction dimensions at the depth at which the bottom portion of the contact part 22a is located. Specifically, first, the position (the depth) in the Z-direction at which the bottom portion of the contact part 22a is present is determined. Then, the X-direction end portion of the gate electrode 10, the interface between the p-type base region 2 and the gate insulating layer 11, etc., at the depth at which the bottom portion of the contact part 22a is present are determined. The distance D and the width W are measured based on the end portion, interface, etc.

For example, as shown in FIG. 3, the source electrode 22 includes a contact part 22b in addition to the contact part 22a. The contact part 22b is located on the contact part 22a and positioned between the insulating layers 12 in the X-direction. The width of the contact part 22b is greater than the width of the contact part 22a. For example, the width of the contact part 22a changes to the width of the contact part 22b in a staircase shape.

As shown in FIG. 2, an upper surface US of the n⁺-type source region 3 may include a first region US1 and a second region US2. The incline with respect to the X-direction of the first region US1 is not less than 0 degrees and not more than 15 degrees. The incline with respect to the X-direction of the second region US2 is not less than 30 degrees and not more than 90 degrees. The X-direction position of the first region US1 is between the X-direction position of the second region US2 and the X-direction position of the contact part 22a. A width W3 of the first region US1 is not less than 87 nm. A width W4 of the second region US2 is not less than 5 nm and not more than 20 nm. The upper limit of the width W3 is not particularly limited, and is designed appropriately according to the width W1 of the contact part 22a, a pitch P of the gate electrodes 10, etc.

In the semiconductor device 100 as shown in FIG. 3, the n⁺-type source region 3 may include a first part 3a and a second part 3b. The first part 3a includes the first region US1 shown in FIG. 2. The second part 3b is positioned between the first region US1 and the insulating layer 12 in the X-direction. For example, the n-type impurity concentration of the second part 3b is less than the n-type impurity concentration of the first part 3a. Therefore, the electrical resistivity of the second part 3b is greater than the electrical resistivity of the first part 3a.

As shown in FIG. 2, a first junction J1 is formed between the n⁻-type drift region 1 and the p-type base region 2. A second junction J2 is formed between the p-type base region 2 and the n⁺-type source region 3. A bottom surface LS of the contact part 22a is positioned higher than the first junction J1 and positioned lower than the second junction J2. A distance D1 (a first distance) in the Z-direction from the first junction J1 to the bottom surface LS is not less than 0.5 times a distance D2 (a second distance) in the Z-direction from the first junction J1 to the second junction J2. In other words, the bottom surface LS is positioned higher than the center between the first junction J1 and the second junction J2.

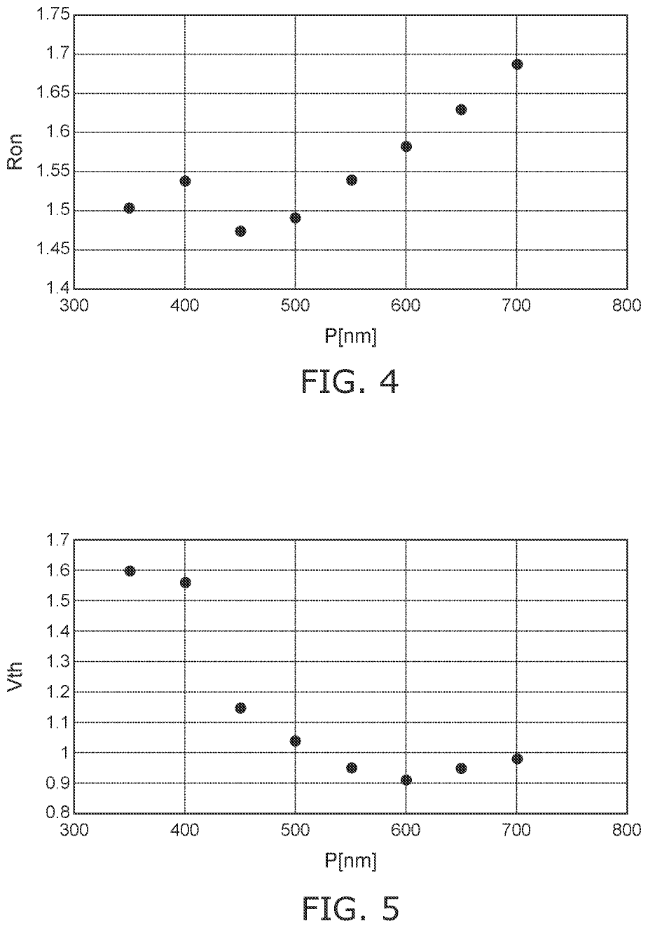

FIGS. 4 to 8 are simulation results of semiconductor device characteristics.

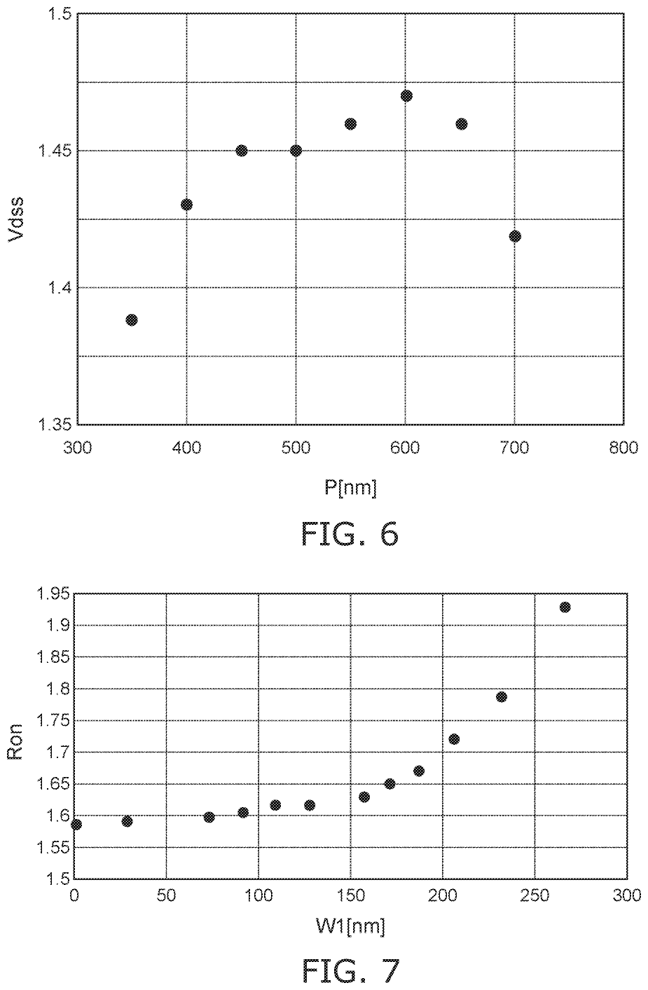

FIG. 4 is a simulation result showing the relationship between a pitch P and an on-resistance Ron. FIG. 5 is a simulation result showing the relationship between the pitch P and a threshold voltage Vth. FIG. 6 is a simulation result showing the relationship between the pitch P and a breakdown voltage Vdss. In FIGS. 4 to 6, the numerical values of the on-resistance Ron, the threshold voltage Vth, and the breakdown voltage Vdss are relative ratios. The threshold voltage Vth is the voltage applied to the gate electrode 10 necessary to turn on the semiconductor device 100. The breakdown voltage Vdss means the maximum voltage that can be applied between the drain electrode 21 and the source electrode 22 when the gate electrode 10 and the source electrode 22 are short-circuited. In the simulation, the width W was set to 160 nm. The length L1 was set to 390 nm. The width W1 was set to 70 nm.

The simulation result of FIG. 4 shows that the on-resistance Ron increased as the pitch P increased. This is because the number of the gate electrodes 10 per unit area decreased as the pitch P increased. The channel area per unit area also decreased as the number of the gate electrodes 10 per unit area decreased. In other words, the channel density decreased. The on-resistance Ron increased when the channel density decreased. On the other hand, the simulation result of FIG. 4 shows that the on-resistance Ron also increased when the pitch P was too narrow. When the pitch P was narrow, the p-type impurity of the p⁺-type contact region 4 easily diffused to the interface vicinity between the p-type base region 2 and the gate insulating layer 11 in the manufacturing processes of the semiconductor device 100. As the p-type impurity concentration of the interface increased, the resistance to the electrons increased, and the on-resistance Ron increased. When the pitch P was not more than 400 nm, the on-resistance Ron increased due to the effect of the on-resistance Ron increase caused by the p-type impurity diffusion increase. However, because such an increase was minor, it is sufficient for the pitch P to be not more than 650 nm from the perspective of the on-resistance Ron.

According to the simulation result of FIG. 5, the threshold voltage Vth increased as the pitch P decreased. Specifically, the threshold voltage Vth increased greatly when the pitch P was not more than 400 nm. This is because when the pitch P was narrow, the p-type impurity concentration of the interface between the p-type base region 2 and the gate insulating layer 11 increased as described above. Accordingly, it is favorable for the pitch P to be not less than 450 nm from the perspective of the threshold voltage Vth.

According to the simulation result of FIG. 6, the breakdown voltage Vdss decreased when the pitch P was narrow or wide. As the pitch P increased, the ratio of the area of the p⁺-type contact region 4 and the area of the contact part 22a between the gate electrodes 10 when viewed along the Z-direction decreased. When the pitch P was excessively wide, holes were not efficiently discharged when breakdown of the semiconductor device 100 occurred, and the breakdown voltage Vdss decreased. On the other hand, when the pitch P was excessively narrow, the p-type impurity concentration of the p-type base region 2 was increased by the effects of the p⁺-type contact region 4. As a result, the depletion layer did not easily extend in the X-direction in the p-type base region 2; and the breakdown voltage Vdss was reduced. Accordingly, from the perspective of the breakdown voltage Vdss, it is favorable for the pitch P to be not less than 450 nm and not more than 650 nm.

According to the simulation results of FIGS. 4 to 6, it is favorable for the pitch P to be not less than 450 nm and not more than 650 nm.

FIG. 7 is a simulation result showing the relationship between the on-resistance Ron and the width W1 of the contact part 22a. The numerical value of the on-resistance Ron in FIG. 7 is a relative ratio. In the simulation, the width W was set to 160 nm. The length L1 was set to 390 nm. The pitch P was set to 600 nm. The result shown in FIG. 7 shows that the on-resistance Ron was substantially constant when the width W1 was not more than 160 nm. When the width W1 was greater than 160 nm, the on-resistance Ron gradually increased. It is considered that this is because the width W1 increased and the p-type impurity easily diffused into the interface vicinity between the p-type base region 2 and the gate insulating layer 11. When the width W1 exceeded 206 nm and reached 230 nm, the on-resistance Ron increased to 10% more than when the width W1 was less than 100 nm. It is therefore favorable for the width W1 to be not more than 206 nm. To further suppress the increase of the on-resistance Ron, it is more favorable for the width W1 to be not more than 160 nm.

It is favorable for the width W1 to be not less than 28 nm. When the width W1 was less than 28 nm, impact ionization was confirmed at the lower end vicinity of the gate insulating layer 11, although the cause is unclear. When impact ionization occurs at the lower end vicinity of the gate insulating layer 11, breakdown of the gate insulating layer 11 may occur, and the semiconductor regions and the gate electrode 10 may conduct. To reduce the likelihood of breakdown of the gate insulating layer 11 and to increase the reliability of the semiconductor device 100, it is favorable for the width W1 to be not less than 28 nm.

According to the simulation result of FIG. 7, it is favorable for the width W1 to be not less than 28 nm and not more than 206 nm.

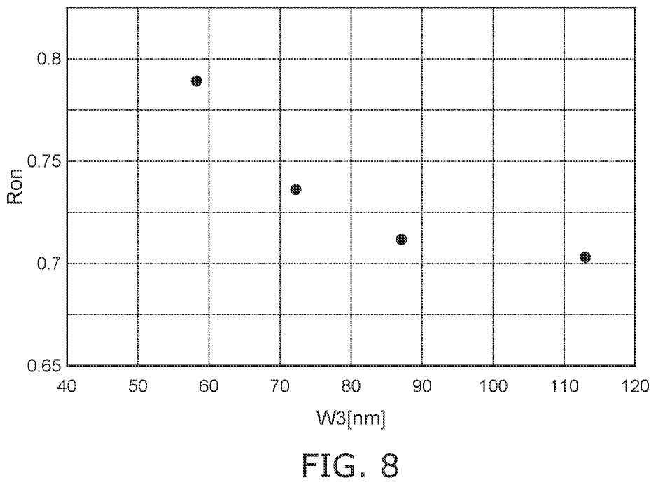

FIG. 8 is an experiment result showing the change of the on-resistance Ron when the width W3 shown in FIG. 2 is changed. In the semiconductor device used in the experiment, the distance D shown in FIG. 2 was designed to be 295 nm. The width W1 of the contact part 22a was designed to be 64 nm. The width W4 was designed to be 20 nm.

From the experiment result shown in FIG. 8, the on-resistance Ron greatly increased when the width W3 was less than 73 nm. This is because when the width W3 was narrow, the contact area between the n⁺-type source region 3 and the source electrode 22 decreased, and the electrical resistance between the n⁺-type source region 3 and the source electrode 22 increased. The upper limit of the width W3 is not particularly limited. As long as the width W3 is not less than 87 nm, the width W3 may be set as appropriate according to the width W1 of the contact part 22a, the distance D, the pitch P, etc. For example, it is favorable for the width W3 to be not less than 87 nm and not more than 200 nm. More favorably, the width W3 is not less than 87 nm and not more than 150 nm.

It is favorable for the bottom portion of the contact part 22a to be such that the distance D1 in the Z-direction from the first junction J1 to the bottom surface LS is not less than 100 nm and not more than 400 nm. It is favorable for the distance D2 in the Z-direction from the first junction J1 to the second junction J2 to be not less than 200 nm and not more than 500 nm. It is favorable for the distance D3 in the Z-direction from the second junction J2 to the bottom surface LS to be not less than 100 nm and not more than 400 nm.

Advantages of the embodiment will now be described.

In the semiconductor device 100, it is favorable for the distance D shown in FIG. 2 to be short. As the distance D is reduced, the channel density can be increased, and the on-resistance of the semiconductor device 100 can be reduced. On the other hand, the threshold voltage of the gate electrode 10 increases when the distance D is too short. Also, the p-type impurity concentration of the region in which the channel is formed increases. There is a possibility that the effect of the on-resistance increase due to the increase of the p-type impurity concentration of the channel region may exceed the effect of the on-resistance reduction due to the increase of the channel density. As a result, the on-resistance of the semiconductor device 100 may increase.

Results of verifications by the inventors of the application showed that it is favorable for the pitch P to be not less than 450 nm and not more than 650 nm as shown in FIGS. 4 to 6. In the simulations shown in FIGS. 4 to 6, the width W of the gate electrode 10 shown in FIG. 2 was set to 160 nm. The thickness of the gate insulating layer 11 was set to 20 nm. In such a case, it is favorable for the distance D to be not less than 250 nm and not more than 450 nm.

It is favorable for the width W of the gate electrode 10 to be set within the range of not less than 160 nm and not more than 240 nm. As described below, the gate electrode 10 is formed by filling a conductive material into an opening formed in the semiconductor layer. When the width W is less than 160 nm, it is difficult to uniformly fill the conductive material; and voids may occur in the gate electrode 10. As a result, the channel formation in the p-type base region 2 may become unstable, and the on-resistance may increase. On the other hand, when the width W is greater than 240 nm, the increase of the on-resistance due to the reduction of the channel density is pronounced. When the pitch P is not less than 450 nm and not more than 650 nm, the thickness of the gate insulating layer 11 is 20 nm, and the width W is 240 nm, it is favorable for the distance D to be not less than 150 nm and not more than 450 nm. In other words, when the width W is set within the range of not less than 160 nm and not more than 240 nm, it is favorable for the distance D to be not less than 150 nm and not more than 450 nm. By setting the distance D within this range, the on-resistance of the semiconductor device 100 can be reduced while suppressing the increase of the threshold voltage of the gate electrode 10.

When the distance D is short, such as not less than 150 nm and not more than 450 nm, it is favorable for the source electrode 22 to include the contact part 22a. By including the contact part 22a, the contact area between the p-type base region 2 and the source electrode 22 and the contact area between the n⁺-type source region 3 and the source electrode 22 can be increased. By increasing the contact area between the p-type base region 2 and the source electrode 22, the discharge of the holes from the p-type base region 2 to the source electrode 22 is promoted. For example, when avalanche breakdown of the semiconductor device 100 occurs, the potential increase of the p-type base region 2 can be suppressed. As a result, the operation of the semiconductor device 100 as a bipolar transistor can be suppressed. In other words, latchup of the semiconductor device 100 can be suppressed, and the avalanche resistance of the semiconductor device 100 can be improved. By increasing the contact area between the n⁺-type source region 3 and the source electrode 22, the electrical resistance between the n⁺-type source region 3 and the source electrode 22 can be reduced, and the on-resistance of the semiconductor device 100 can be reduced.

When the contact part 22a is included, the width W1 of the contact part 22a also affects the characteristics of the semiconductor device 100. In particular, when the distance D is short, such as 150 nm to 450 nm, the characteristics of the semiconductor device 100 may greatly fluctuate due to the width W1. Specifically, when the width W1 increases to be not less than 230 nm as shown in FIG. 7, the on-resistance Ron increases not less than 10% compared to when the width W1 is not more than 100 nm. When the width W1 is not more than 28 nm, much impact ionization occurs at the gate insulating layer 11 vicinity; and the reliability of the semiconductor device 100 degrades. Accordingly, it is favorable for the width W1 to be not less than 28 nm and not more than 206 nm.

As described above, the contact area between the n⁺-type source region 3 and the source electrode 22 can be increased by increasing the width W3 of the n⁺-type source region 3 positioned between the gate insulating layer 11 and the contact part 22a. On the other hand, as the width W3 increases, the width W1 of the contact part 22a decreases, and the reliability of the semiconductor device 100 may degrade. In this regard, according to the experiment result shown in FIG. 8, it is favorable for the width W3 shown in FIG. 2 to be not less than 87 nm. By setting the width W3 to be not less than 87 nm, the on-resistance of the semiconductor device 100 can be reduced while suppressing degradation of the reliability of the semiconductor device 100.

In particular, in the semiconductor device 100 illustrated in FIGS. 1 to 3, the upper surface US of the n⁺-type source region 3 includes the first region US1 and the second region US2. The second region US2 is formed when the contact part 22a is formed by a manufacturing method described below. The width W3 of the first region US1 is narrower if the second region US2 is present. Accordingly, more detailed control of the width W3 is necessary.

Results of verifications by the inventors showed that in the n⁺-type source region 3, the electrical resistivity of the second part 3b may be greater than the electrical resistivity of the first part 3a. It is considered that this is because the n-type impurity of the second part 3b diffuses into the periphery because the width W4 of the second part 3b is less than the width W3 of the first part 3a. Accordingly, when the second part 3b is present and the width of the first part 3a is narrow, the contact resistance between the n⁺-type source region 3 and the source electrode 22 tends to increase. However, even when the second part 3b is present, by setting the width W3 to be not less than 87 nm as described above, the on-resistance of the semiconductor device 100 can be reduced while suppressing degradation of the reliability of the semiconductor device 100.

By including the second part 3b, the current density of the semiconductor device 100 can be adjusted. In other words, the second part 3b is unfavorable from the perspective of reducing the on-resistance. On the other hand, the electrical resistivity of the second part 3b is greater than the electrical resistivity of the first part 3a. Therefore, the voltage drop when a current flows through the second part 3b is greater than the voltage drop when a current flows through the first part 3a. For example, a large current flows in the semiconductor device 100 when the semiconductor device 100 is in a short-circuit state. At this time, the current that flows in the semiconductor device 100 can be suppressed because the voltage drop due to the second part 3b is large. By including the second part 3b and setting the width W3 to be not less than 87 nm, the current density in a short-circuit can be reduced while reducing the on-resistance of the semiconductor device 100.

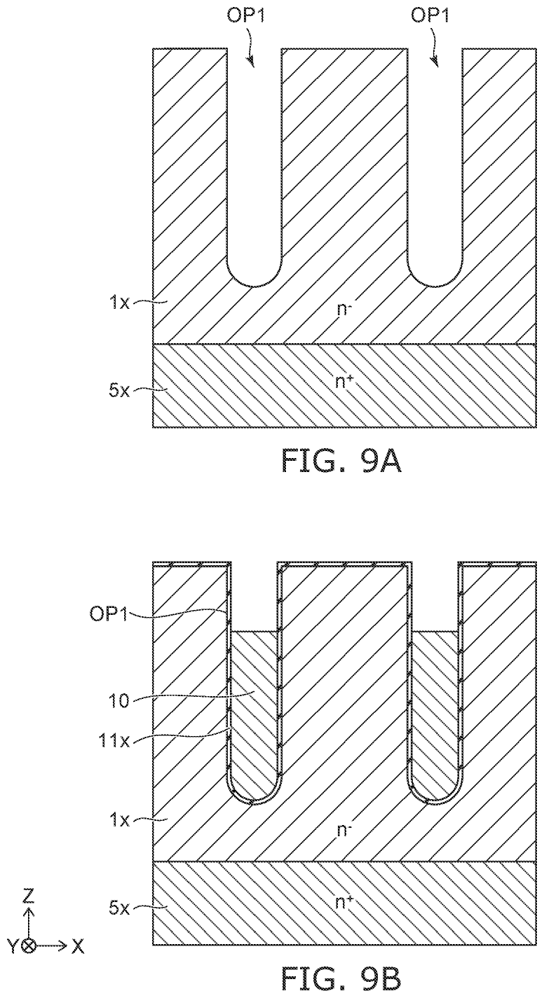

FIGS. 9A, 9B, 10A, 10B, 11A, 11B, 12A, 12B, and 13 are cross-sectional views showing a method for manufacturing the semiconductor device according to the embodiment.

First, a semiconductor substrate that includes an n⁺-type semiconductor layer 5x and an n⁻-type semiconductor layer 1x is prepared. The n⁻-type semiconductor layer 1x is located on the n⁺-type semiconductor layer 5x. Openings OP1 are formed in the upper surface of the n⁻-type semiconductor layer 1x by photolithography and reactive ion etching (RIE). As shown in FIG. 9A, multiple openings OP1 are formed in the X-direction; and each opening OP1 extends in the Y-direction.

An insulating layer 11x is formed by thermal oxidation along the surface of the n⁻-type semiconductor layer 1x. A conductive layer is formed by chemical vapor deposition (CVD) on the insulating layer 11x. The conductive layer includes, for example, polysilicon. The openings OP1 are filled with the conductive layer. The upper surface of the conductive layer is caused to recede by wet etching. As a result, as shown in FIG. 9B, the conductive layer is divided into a plurality; and the gate electrode 10 is formed inside each opening OP1.

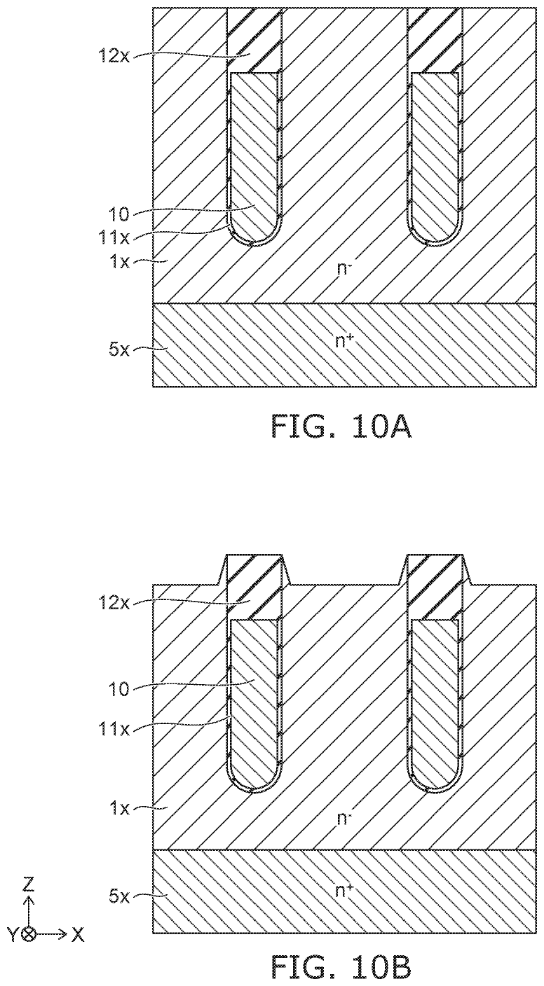

An insulating layer 12x is formed on the gate electrode 10. The opening OP1 is filled with the insulating layer 12x. Chemical dry etching (CDE) is performed until the upper surface of the n⁻-type semiconductor layer 1x is exposed. As a result, as shown in FIG. 10A, a portion of the insulating layer 11x and a portion of the insulating layer 12x are removed; and the upper surface of the n⁻-type semiconductor layer 1x is exposed.

A portion of the n⁻-type semiconductor layer 1x between the insulating layers 12x is removed by CDE. The gas of the CDE is selected to have a higher etching rate for the semiconductor than for the insulating layer. For example, HBr (hydrogen bromide) or the like is used as the gas. When performing CDE, an etching rate difference occurs between the portion at the vicinity of the insulating layer 12x and the portion separated from the insulating layer 12x. It is difficult to remove the n⁻-type semiconductor layer 1x at the vicinity of the insulating layer 12x. As a result, as shown in FIG. 10B, the upper surface of the portion at the vicinity of the insulating layer 12x is inclined, and the position of the upper surface of the portion at the vicinity of the insulating layer 12x is higher than the position of the upper surface of the portion separated from the insulating layer 12x.

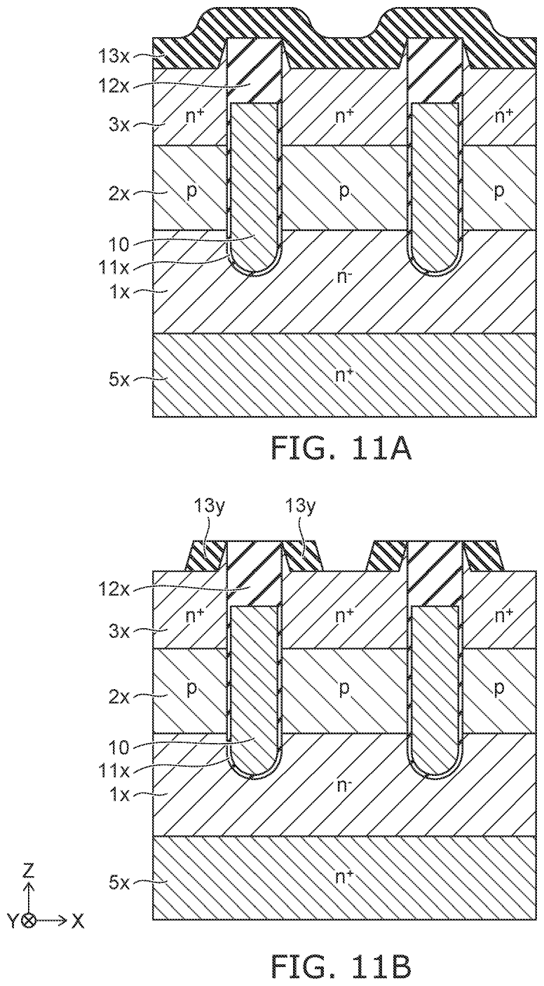

A p-type semiconductor region 2x and an n⁺-type semiconductor region 3x are formed by sequentially ion-implanting a p-type impurity and an n-type impurity into the upper surface of the n⁻-type semiconductor layer 1x. As shown in FIG. 11A, an insulating layer 13x that covers the n⁺-type semiconductor region 3x and the insulating layer 12x is formed by CVD. For example, the insulating layer 13x includes an insulating material such as silicon oxide, silicon nitride, etc. As described below, the material of the insulating layer 13x is modifiable as appropriate as long as the insulating layer 13x can be used as a mask when etching the semiconductor layers.

A portion of the insulating layer 13x is positioned above the two ends of the n⁺-type semiconductor region 3x in the X-direction. Another portion of the insulating layer 13x is positioned above the X-direction center of the n⁺-type semiconductor region 3x. Part of the insulating layer 13x is removed by anisotropic etching until a portion of the upper surface of the n⁺-type semiconductor region 3x is exposed. The thickness (the dimension in the Z-direction) of the portion of the insulating layer 13x is greater than the thickness of the other portion of the insulating layer 13x. Therefore, as shown in FIG. 11B, the thin portion of the insulating layer 13x is removed; and the thick portion of the insulating layer 13x remains. Specifically, the insulating layer 13x remains at the sides of the insulating layers 12x (above the two ends of the n⁺-type semiconductor region 3x); and the other portions of the insulating layer 13x are removed. The X-direction central portion of the n⁺-type semiconductor region 3x is exposed. As a result, a mask 13y that covers only the n⁺-type semiconductor region 3x at the vicinity of the insulating layer 12x is formed.

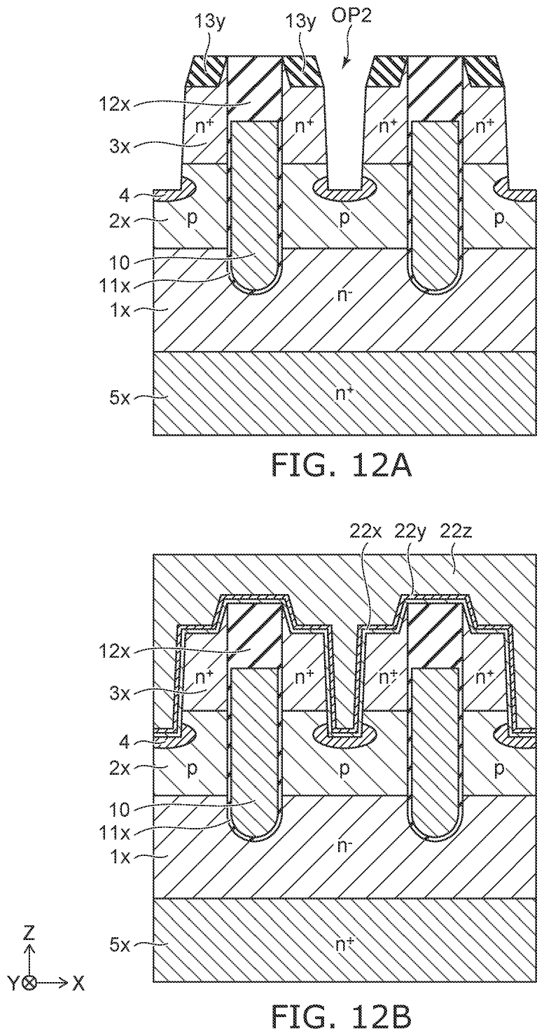

A portion of the n⁺-type semiconductor region 3x and a portion of the p-type semiconductor region 2x are removed using the mask 13y. An opening OP2 is formed thereby. As shown in FIG. 12A, the p⁺-type contact region 4 is formed by ion-implanting a p-type impurity into the bottom surface of the opening OP2 via the opening OP2.

The mask 13y is removed. A metal layer 22x and a metal layer 22y are formed along the surface of the p-type semiconductor region 2x and the surface of the n⁺-type semiconductor region 3x by sputtering. The metal layer 22x includes titanium nitride. The metal layer 22y includes titanium. As shown in FIG. 12B, a metal layer 22z that fills the opening OP2 is formed on the metal layer 22y by sputtering. The metal layer 22z includes aluminum.

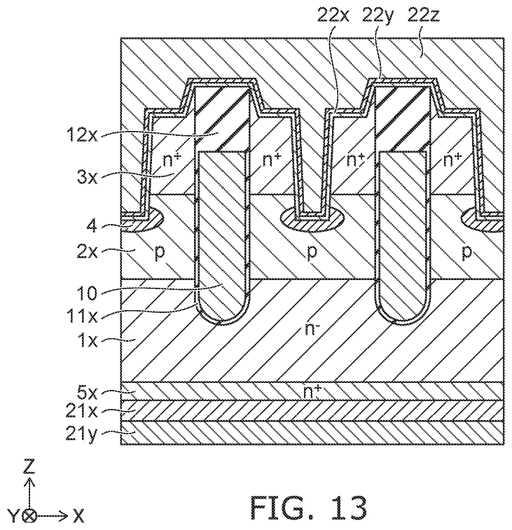

The lower surface of the n⁺-type semiconductor layer 5x is polished until the n⁺-type semiconductor layer 5x has a prescribed thickness. As shown in FIG. 13, a metal layer 21x and a metal layer 21y are formed by sputtering on the lower surface of the polished n⁺-type semiconductor layer 5x. The metal layer 21x includes titanium. The metal layer 21y includes aluminum. The semiconductor device 100 according to the embodiment is manufactured by the processes described above.

The n⁻-type semiconductor layer 1x shown in FIG. 13 corresponds to the n⁻-type drift region 1 shown in FIG. 1. The p-type semiconductor region 2x corresponds to the p-type base region 2. The n⁺-type semiconductor region 3x corresponds to the n⁺-type source region 3. The portion of the n⁺-type semiconductor region 3x at the vicinity of the insulating layer 12x corresponds to the first part 3a. The portion of the n⁺-type semiconductor region 3x separated from the insulating layer 12x corresponds to the second part 3b. The n⁺-type semiconductor layer 5x corresponds to the n⁺-type drain region 5. The insulating layer 11x corresponds to the gate insulating layer 11. The insulating layer 12x corresponds to the insulating layer 12. The metal layer 21x corresponds to the drain electrode 21. The metal layers 22x to 22z correspond to the source electrode 22. A portion of the metal layer 22x, a portion of the metal layer 22y, and a portion of the metal layer 22z are positioned inside the opening OP2. The portion of the metal layer 22x, the portion of the metal layer 22y, and the portion of the metal layer 22z correspond to the contact part 22a.

It is favorable for the misalignment in the X-direction of the contact part 22a to be small when manufacturing the semiconductor device 100. For example, when the position of the contact part 22a is misaligned, the distance between the contact part 22a and one insulating layer 11x decreases. When the p⁺-type contact region 4 is formed, the p-type impurity easily diffuses into the vicinity of the insulating layer 11x. As a result, the threshold voltage of the gate electrode 10 is increased. Also, when the position of the contact part 22a is misaligned, the distance between the contact part 22a and the other insulating layer 11x increases. The position at which impact ionization occurs may change, and the reliability of the semiconductor device 100 may degrade.

According to the manufacturing method according to the embodiment, the mask 13y is used as shown in FIG. 12A when forming the opening OP2. The position of the mask 13y is determined based on the thickness difference between the portions of the insulating layer 13x. Specifically, the mask 13y is formed only at the side of the insulating layer 12x, and is not formed at the position separated from the insulating layer 12x. In other words, the position of the mask 13y is self-aligningly determined according to the position of the insulating layer 12x. Accordingly, misalignment of the mask 13y can be suppressed even when the spacing between the insulating layers 12x is narrow. As a result, misalignment of the opening OP2 formed using the mask 13y also is suppressed.

The embodiment of the invention is favorable in a semiconductor device in which a conductive body (a so-called field plate electrode) is not located below the gate electrode 10. Generally, a field plate electrode is positioned between the n⁻-type drift region 1 and the gate electrode 10 in the Z-direction and is electrically connected with the gate electrode 10 or the source electrode 22. When a field plate electrode is included, it is necessary to provide a thick insulating layer between the n⁻-type drift region 1 and the field plate electrode. Therefore, it becomes necessary to set the pitch of the gate electrodes 10 to be 450 nm to 650 nm. By applying the configuration described above to a semiconductor device in which a field plate electrode is not included, the on-resistance of the semiconductor device 100 can be effectively reduced while suppressing an increase of the threshold voltage of the gate electrode 10.

Embodiments of the invention may include the following features.

### (Feature 1)

A semiconductor device, comprising:
a first electrode;
a first semiconductor region located on the first electrode, the first semiconductor region being of a first conductivity type;
a pair of gate electrodes located on the first semiconductor region with gate insulating layers respectively interposed, a distance between the gate insulating layers in a second direction perpendicular to a first direction being not less than 150 nm and not more than 450 nm, the first direction being from the first electrode toward the first semiconductor region;
a second semiconductor region located between the pair of gate electrodes, the second semiconductor region being of a second conductivity type;
a third semiconductor region located on the second semiconductor region, the third semiconductor region being of the first conductivity type; and
a second electrode located on the pair of gate electrodes with insulating layers respectively interposed, the second electrode including a contact part contacting the third semiconductor region and a portion of the second semiconductor region in the second direction, a length in the second direction of a bottom portion of the contact part being greater than 28 nm and not more than 206 nm.

### (Feature 2)

The device according to Feature 1, wherein
an upper surface of the third semiconductor region includes:
   a first region having an incline with respect to the second direction of not less than 0 degrees and not more than 15 degrees; and
   a second region having an incline with respect to the second direction of not less than 30 degrees, and
a position in the second direction of the first region is between a position in the second direction of the second region and a position in the second direction of the contact part.

### (Feature 3)

The device according to Feature 2, wherein
a length in the second direction of the first region is not less than 87 nm, and
a length in the second direction of the second region is not less than 5 nm and not more than 20 nm.

### (Feature 4)

The device according to Feature 2 or 3, wherein
the third semiconductor region includes:
   a first part contacting the contact part, the first part including the first region; and
   a second part positioned between the second region and the insulating layer, the second part including the second region, and
a first-conductivity-type impurity concentration of the second part is less than a first-conductivity-type impurity concentration of the first part.

### (Feature 5)

The device according to any one of Features 1 to 4, wherein
a first distance to a bottom surface of the contact part from a first junction between the first semiconductor region and the second semiconductor region is greater than 0.5 times a second distance from the first junction to a second junction between the second semiconductor region and the third semiconductor region.

### (Feature 6)

The device according to any one of Features 1 to 5, further comprising:
a fourth semiconductor region located between the second semiconductor region and the contact part, the fourth semiconductor region being of the second conductivity type,
a second-conductivity-type impurity concentration of the fourth semiconductor region being greater than a second-conductivity-type impurity concentration of the second semiconductor region.

### (Feature 7)

The device according to any one of Features 1 to 6, wherein
a sum of the distance between the gate insulating layers, the length in the second direction of one of the pair of gate electrodes, and 2 times a thickness of the gate insulating layer is not less than 450 nm and not more than 650 nm.

In the embodiments above, the relative levels of the impurity concentrations between the semiconductor regions can be confirmed using, for example, a scanning capacitance microscope (SCM). The carrier concentration in each semiconductor region can be considered to be equal to the activated impurity concentration in each semiconductor region. Accordingly, the relative levels of the carrier concentrations between the semiconductor regions also can be confirmed using SCM. The impurity concentration in each semiconductor region can be measured by, for example, secondary ion mass spectrometry (SIMS).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor device, comprising:
a first electrode;
a first semiconductor region located on the first electrode, the first semiconductor region being of a first conductivity type;
a pair of gate electrodes located on the first semiconductor region with gate insulating layers respectively interposed, a distance between the gate insulating layers in a second direction perpendicular to a first direction being not less than 150 nm and not more than 450 nm, the first direction being from the first electrode toward the first semiconductor region;
a second semiconductor region located between the pair of gate electrodes, the second semiconductor region being of a second conductivity type;
a third semiconductor region located on the second semiconductor region, the third semiconductor region being of the first conductivity type; and
a second electrode located on the pair of gate electrodes with insulating layers respectively interposed, the second electrode including a contact part contacting the third semiconductor region and a portion of the second semiconductor region in the second direction, a length in the second direction of a bottom portion of the contact part being greater than 28 nm and not more than 206 nm.

2. The device according to claim 1, wherein
an upper surface of the third semiconductor region includes:
a first region having an incline with respect to the second direction of not less than 0 degrees and not more than 15 degrees; and
a second region having an incline with respect to the second direction of not less than 30 degrees, and
a position in the second direction of the first region is between a position in the second direction of the second region and a position in the second direction of the contact part.

3. The device according to claim 2, wherein
a length in the second direction of the first region is not less than 87 nm, and
a length in the second direction of the second region is not less than 5 nm and not more than 20 nm.

4. The device according to claim 2, wherein
the third semiconductor region includes:
a first part contacting the contact part, the first part including the first region; and
a second part positioned between the second region and the insulating layer, the second part including the second region, and
a first-conductivity-type impurity concentration of the second part is less than a first-conductivity-type impurity concentration of the first part.

5. The device according to claim 1, wherein
a first distance to a bottom surface of the contact part from a first junction between the first semiconductor region and the second semiconductor region is greater than 0.5 times a second distance from the first junction to a second junction between the second semiconductor region and the third semiconductor region.

6. The device according to claim 1, further comprising:
a fourth semiconductor region located between the second semiconductor region and the contact part, the fourth semiconductor region being of the second conductivity type,
a second-conductivity-type impurity concentration of the fourth semiconductor region being greater than a second-conductivity-type impurity concentration of the second semiconductor region.

7. The device according to claim 1, wherein
a sum of the distance between the gate insulating layers, the length in the second direction of one of the pair of gate electrodes, and 2 times a thickness of the gate insulating layer is not less than 450 nm and not more than 650 nm.
